(19) United States
(12) Patent Application Publication
(10) Pub. No.: US 2018/0097014 A1
(43) Pub. Date: Apr. 5, 2018

(54) FDSOI-TYPE FIELD-EFFECT TRANSISTORS

(71) Applicants: STMicroelectronics (Crolles 2) SAS, Crolles (FR); STMicroelectronics SA, Montrouge (FR); Commissariat A L'Energie Atomique et aux Energies Alternatives, Paris (FR)

(72) Inventors: Vincent Barral, Grenoble (FR); Nicolas Planes, La Terrasse (FR); Antoine Cros, Grenoble (FR); Sebastien Haendler, Montbonnot (FR); Thierry Poiroux, Voiron (FR); Olivier Weber, Grenoble (FR); Patrick Scheer, Saint Martin D'heres (FR)

(73) Assignees: STMicroelectronics (Crolles 2) SAS, Crolles (FR); STMicroelectronics SA, Montrouge (FR); Commissariat A L'Energie Atomique et aux Energies Alternatives, Paris (FR)

(21) Appl. No.: 15/722,340

(22) Filed: Oct. 2, 2017

(30) Foreign Application Priority Data
Oct. 4, 2016 (FR) 1659574

(51) Int. Cl. H01L 27/12

(52) U.S. Cl. CPC H01L 27/1203; B82Y 99/00

(57) ABSTRACT

An electronic chip includes FDSOI-type field-effect transistors. The transistor each have a channel region that is doped at an average level in a range from 10¹⁶ to 5*10¹⁷ atoms/cm³ with a conductivity type opposite to that of a conductivity type for the dopant in the drain and source regions.

### PRIORITY CLAIM

This application claims the priority benefit of French Application for Patent No. 1659574, filed on Oct. 4, 2016, the disclosure of which is hereby incorporated by reference in its entirety.

### TECHNICAL FIELD

The present disclosure relates to an electronic chip comprising transistors, in particular, field-effect transistors of FDSOI (“Fully Depleted Semiconductor On Insulator”) type.

### BACKGROUND

In certain analog circuits, such as measurement circuits, it is needed to form field-effect transistors having as identical characteristics as possible. For example, two transistors may form a current mirror to copy a measurement signal, and the measurement is then all the more accurate as the electrical characteristics of the two transistors, such as the threshold voltages, are close. To decrease differences between the transistors characteristics due to the manufacturing method, the transistors are formed simultaneously and are close to each other. However, there remain differences between the transistor characteristics. Such differences may result from differences in the number and the positions of the dopant atoms or from configuration differences such as gate insulator thickness or channel region shape differences. Such differences may be due to irregularities resulting from the atomic or granular structure of the material. Such irregularities similarly affect elements of the device separated by a distance shorter than a so-called irregularity correlation length value, and randomly affect elements separated by a distance greater than the correlation length. The correlation length is here smaller than the dimensions separating the transistors, which are thus affected differently by the irregularities.

Further, when a plurality of specimens of a logic or analog integrated circuit are formed, simultaneously from a semiconductor wafer or successively from different semiconductor wafers originating from a same batch of wafers or originating from different batches, the obtained circuits do not have strictly identical performances. This is due to differences in the implementation of the methods of forming the wafers, and then the circuits, such differences being capable of similarly affecting all the transistors of a circuit. For example, the circuits may consume different leakage currents when they are powered. Such leakage current differences raise various design and implementation issues. A problem also is that certain circuits having too high leakage currents may have to be rejected.

Electrical characteristic differences between simultaneously manufactured transistors and/or integrated circuits thus need to be decreased. Such a need is particularly present in the case of FDSOI transistors, despite a current prejudice.

### SUMMARY

Thus, an embodiment provides an electronic chip comprising FDSOI-type field-effect transistors having their channel regions doped at an average level in the range from 10¹⁶ to 5*10¹⁷ atoms/cm³ with a conductivity type opposite to that of the drain and source regions.

According to an embodiment, the channel regions have thicknesses in the range from 2.5 to 10 nm.

According to an embodiment, the gate surface area of the transistors is greater than 1 μm².

According to an embodiment, said transistors are the two transistors of a current mirror.

According to an embodiment, the transistors are transistors having a channel of a same conductivity type connected to a power supply circuit.

According to an embodiment, the doping level of each of the channel regions is lower than 5*10¹⁷ atoms/cm³.

According to an embodiment, the thickness of the channel regions is in the range from 5.5 to 6.5 μm and the average doping level of the channel regions is in the range from 5*10¹⁶ to 10¹⁷ atoms/cm³.

According to an embodiment, the transistors are located above rear gates.

According to an embodiment, the rear gates are doped with the conductivity type opposite to that of the channel regions.

### BRIEF DESCRIPTION OF THE DRAWINGS

The foregoing and other features and advantages will be discussed in detail in the following non-limiting description of specific embodiments in connection with the accompanying drawings, wherein:

FIG. 1 illustrates differences between threshold voltages of field-effect transistors according to their gate surface area;

FIG. 2 illustrates different leakage current values of an assembly of circuits;

FIG. 3 is a simplified cross-section view of an embodiment of two neighboring transistors connected as a current mirror;

FIG. 4 illustrates various threshold voltages according to a channel region thickness;

FIG. 5 illustrates differences between threshold voltages of field-effect transistors according to their gate surface area;

FIG. 6 is a partial simplified cross-section view of an embodiment of a FDSOI-type structure comprising a plurality of circuits; and

FIG. 7 illustrates currents consumed by circuits.

### DETAILED DESCRIPTION

The same elements have been designated with the same reference numerals in the various drawings and, further, the various drawings are not to scale. For clarity, only those steps and elements which are useful to the understanding of the described embodiments have been shown and are detailed. In the following description, when reference is made to terms qualifying a relative position, such as term “top”, “bottom”, “upper”, etc., reference is made to the orientation of the concerned element in the drawings. Unless otherwise specified, expression “in the order of” means to within 10%, preferably to within 5%.

FIG. 1 schematically illustrates differences ΔV_{T} between threshold voltages of field-effect transistors according to their gate surface area S. The gate surface corresponds, in a field-effect transistor, to the surface of coverage of the channel region by the gate. Two curves 10 and 12 correspond to two types of field-effect transistors.

As mentioned, when a pair of two neighboring transistors designed to be identical is manufactured, there may randomly exist a difference between the threshold voltages of the transistors really obtained. For each gate surface area value, when a large number of transistor pairs is manufactured, for example, more than one thousand pairs of transistors, a difference between threshold voltages, or variance of the threshold voltages, corresponding to value ΔV_{T}, is obtained.

Curve 10 corresponds to field-effect transistors formed inside and on top of a solid semiconductor substrate, that is, transistors having their channel regions located in portions of the substrate. In the example of N-channel transistors, the channel regions are P-type doped, at values for example in the range from 10¹⁸ to 10¹⁹ atoms/cm³.

Curve 12 corresponds to FDSOI-type field effect transistors, that is, the channel region of each transistor is a portion of an upper semiconductor layer which extends on a common insulating layer resting on a common support.

The support, the insulating layer, and the upper semiconductor layer thus form a FDSOI-type structure.

The FDSOI structure corresponds to an SOI (“Semiconductor On Insulator”) structure where the thickness of the upper semiconductor layer is for example smaller than approximately 10 nm. The channel regions are made of intrinsic semiconductor, that is, a semiconductor which is not intentionally doped and comprises in average less than 10¹⁶ dopant atoms per cm³.

As can be seen, for a given gate surface area, difference ΔV_{T} is generally smaller for FDSOI transistors. Difference ΔV_{T} decreases when the gate surface area of the transistor increases.

However, conversely to a current prejudice, this advantage of FDSOI transistors only exists for transistors having a small gate surface area, which are the most currently used in logic circuits. The inventors have observed that, in the case of FDSOI transistors, differences ΔV_{T} no longer decrease if the gate surface area of transistors is increased beyond a value in the order of 1 μm². When the gate surface areas are 100 μm², differences ΔV_{T} for FDSOI transistors may become greater than differences ΔV_{T} for transistors on a solid substrate. For FDSOI-type transistors, small differences ΔV_{T}, for example, in average smaller than 1 mV, cannot be obtained, while this is possible for transistors on a solid substrate.

FDSOI-type transistors having particularly small differences ΔV_{T} are desired to be obtained, particularly for transistors having dimensions greater than approximately 1 μm². It is also desired to obtain pairs of transistors having, for similar differences ΔVT, gate surface areas smaller than those of transistors on a solid substrate.

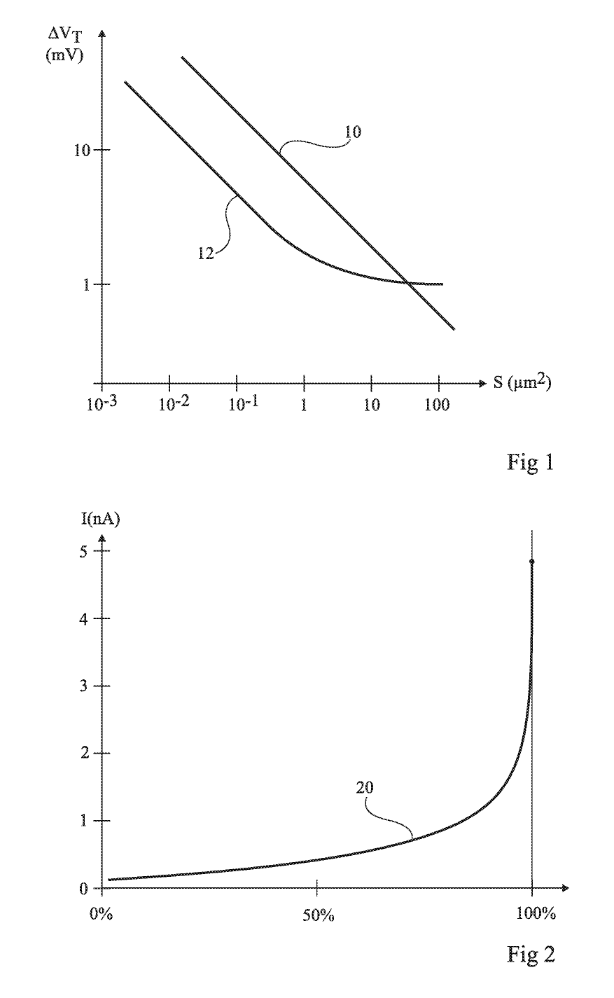

Although the problems described hereabove in relation with FIG. 1 essentially concern FDSOI transistors having a large gate surface area, other problems, described hereafter in relation with FIG. 2, concern FDSOI transistors having a small gate surface area.

FIG. 2 illustrates the current I consumed by circuits provided to be identical and formed simultaneously inside and on top of a same FDSOI-type wafer. The circuits are classified, between 0 and 100% of the circuits, by order of increasing current I.

Each circuit comprises a high number of FDSOI-type transistors, for example, more than one thousand transistors. When the circuit is connected to a power supply circuit, each transistor consumes in the non-conducting state a leakage current which depends on the specific transistor threshold voltage. The current generally consumed by the circuit is the sum of the currents consumed by all the circuit transistors and thus is not a function of the individual electrical characteristics of the transistors, but is a function of the average electrical characteristics of all the transistors.

It could thus be expected for the currents consumed by circuits designed to be identical and comprising a high number of transistors to be close to an average value. However, the inventors have observed that there remain large differences between the currents consumed by such circuits, for example, approximately 1% of the circuits consume a current approximately 5 times greater than current I corresponding to 90% of the circuits. A problem is that the power supply circuit should then be designed to supply the high current consumed by these approximately 1% of the circuits or that the circuits having the highest power consumption should be rejected.

It is thus desired to obtain circuits designed to be identical having decreased differences between consumed currents.

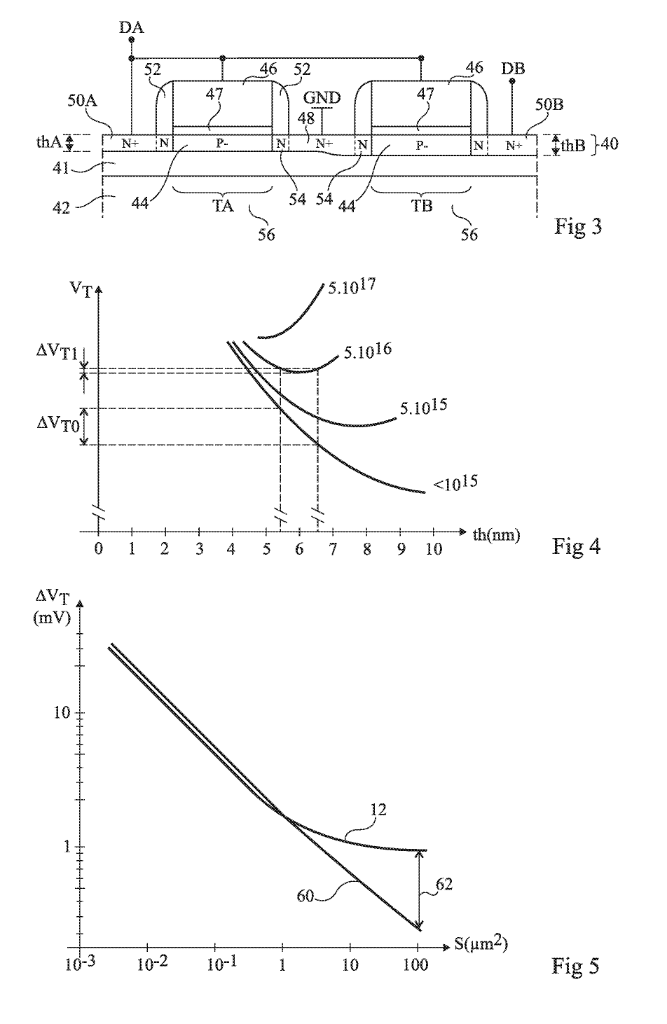

FIG. 3 is a simplified cross-section view of an embodiment of two neighboring transistors TA and TB. Transistors TA and TB have been designed to be identical and have been manufactured simultaneously.

Transistors TA and TB are FDSOI-type N-channel MOS transistors arranged inside and on top of an upper semiconductor layer 40. Layer 40 is arranged on an insulator layer 41 covering a support 42. Transistors TA and TB each comprise a channel region 44 located (or capable of forming) under a gate 46 insulated by an insulator 47. Channel region 44 is located between a source region 48, for example, common to transistors TA and TB, and a drain region 50A, 50B. Spacers 52 cover the sides of each gate 46, and the drain and source regions are continued under the spacers by N-type doped regions 54. Regions 54 are less heavily doped than drain and source regions 50A, 50B, and 48. As an example, the transistors are connected as a current mirror between an input node DA and an output node DB, the common source being connected to a ground GND. The gate surface area is the surface area in top view of the channel region located under the gate. This surface area may be greater than 1 μm². As an example, a region 56 of support 42 located under each transistor may be doped, for example, with the same conductivity type as the drain and source regions of the transistor (that is, a conductivity type opposite to that of channel region 44), and provided with a contact, not shown. Region 56 then forms a rear gate of the transistor enabling to act on the electrical characteristics of the transistor by application of a voltage on the rear gate.

Conversely to previously-mentioned FDSOI-type transistors having an intrinsic semiconductor channel region, it is here provided to use, in the example of N-channel transistors, transistors TA and TB having their channel regions 44 P-type doped (P−) at levels in the range from 10¹⁶ to 5*10¹⁷ atoms/cm³, for example, from 5*10¹⁶ to 10¹⁷ atoms/cm³. During the manufacturing of transistors, this may be obtained, for example, by doping regions 44 at a dose in the range from 10¹² to 2*10¹³ atoms/cm² before forming gates 46. The effect obtained by this doping is described hereafter in relation with FIG. 4.

FIG. 4 schematically illustrates threshold voltages of FDSOI-type transistors according to thickness th of the channel region. The cases of channel regions doped to 5*10¹⁵, 5*10¹⁶ and 5*10¹⁷ atoms/cm³, as well as the case of an intrinsic semiconductor channel region (<10¹⁵ atoms/cm³), for which the threshold voltage continuously decreases when the thickness of the channel region increases, have been shown.

Although transistors TA and TB are designed to be identical, they may have in practice a channel region thickness difference. As an example, for a targeted 6-nm thickness, transistors TA and TB have channel region thicknesses in the range from 5.5 nm to 6.5 nm. In the case of an intrinsic semiconductor channel region, the difference between the threshold voltages corresponding to values 5.5 and 6.5 nm is equal to a value ΔV_{T0}. When the doping level of the channel region is increased, this difference starts by decreasing, reaches a minimum value ΔV_{T1} for an optimal doping level of 5*10¹⁶ atoms/cm³, and then increases when the doping level exceeds the optimal value.

Transistors TA and TB having a specifically doped channel region have almost identical threshold voltages, although these transistors may have different channel region thicknesses. Thereby, by using transistors having a channel region doped to a level close to the optimal value, the differences between threshold voltages of large transistors are decreased, and the differences between currents consumed by circuits designed to be identical are decreased.

Indeed, in the case of a pair of transistors designed to be identical, there may remain a difference between average thicknesses thA (for transistor TA) and thB (for transistor TB) of the channel regions when the gate surface area is in the range from 1 μm² to more than 100 μm². This difference results from thickness irregularities of the upper semiconductor layer of the FDSOI structure from which the transistors have been manufactured. Such irregularities are local, that is, their correlation length is in the range from 1 to 5 μm, and affect neighboring transistors TA and TB differently. The fact of using FDSOI transistors having a specifically doped channel region enables to avoid for such thickness differences to cause threshold voltage differences.

For circuits designed to be identical, upper semiconductor layer 40 may have an average thickness in a first circuit and a different average thickness in a second circuit. Such a difference results from thickness irregularities of semiconductor layer 40, which generally affect the first circuit and the second circuit in different ways. The first and the second circuit may be formed inside and on top of a same wafer, inside and on top of different wafers of a same batch of wafers, or inside and on top of wafers from two different batches. Thus, in the first circuit, the FDSOI transistors have in average a channel thickness different from that of the FDSOI transistors of the second circuit. However, the use of FDSOI transistors having a specifically-doped channel region enables to avoid for such average thickness differences to cause differences in the consumed current.

Thus, the thickness irregularities of the upper semiconductor layer of the FDSOI substrate are formed, on the one hand, of local irregularities, which cause differences between threshold voltages of neighboring transistors designed to be identical and, on the other hand, of irregularities having a correlation length greater than the circuit dimensions, which cause differences within a set of circuits designed to be identical. However, the use of FDSOI transistors having a specifically-doped channel region enables to avoid the consequences of such irregularities both on the threshold voltage difference of neighboring transistors and on the differences between the currents consumed by the circuits.

In a FDSOI transistor having a doped channel region, the doping of the channel regions results in increasing the threshold voltage with respect to the threshold voltage which corresponds to an intrinsic semiconductor channel region, or intrinsic threshold voltage. For a fixed doping level, the number of dopant atoms present in the channel region is all the higher as the thickness of the channel region is large, and thus the effect of the doping of the channel region increases when this thickness increases. In the shown example, when the channel region thickness varies from 5.5 nm to 6.5 nm, the intrinsic threshold voltage decreases and the effect of the doping increases for each of the illustrated doping levels. In this example, for the optimal 5*10¹⁶-atoms/cm³ doping level, the increase of the effect of the doping compensates for the intrinsic threshold voltage decrease. Such a doping level provides minimum difference ΔV_{T1}. When the thickness of the channel region increases from 5.5 nm to 6.5 nm, the threshold voltage decreases if the doping level is lower than the optimal value, and this threshold voltage increases if the doping level is greater than the optimal value.

Although a 5*10¹⁶-atoms/cm³ optimal doping level value is described herein, the optimal value of the doping level depends on structural parameters such as the gate lengths of the transistors, the average thickness of the semiconductor layer of the FDSOI structure, or also the gate insulator thickness, and also depends on the transistor materials, for example, on the material of the gate insulator. Such an optimal value may be determined, for example, by a digital simulation. As an example, for transistors designed to be identical, the doping level of channel regions 44 is in the range from 80% to 125% of the optimal value thus determined.

FIG. 5 illustrates differences between threshold voltages ΔV_{T} of FDSOI transistors according to their gate surface area. Curve 12, already shown in FIG. 1, corresponds to FDSOI transistors having an intrinsic semiconductor channel region. Curve 60 corresponds to FDSOI transistors having as a doping level of the channel region the optimal value described in relation with FIG. 4. Curves 12 and 60 have been obtained from experimental values. For each gate surface value, when a large number of transistor pairs are manufactured, the difference between threshold voltages obtained in average corresponds to value ΔV_{T}.

For gate surface areas greater than approximately 1 μm², a decrease in the differences between the transistor threshold voltages is obtained. Decrease 62 reaches a factor 5 for gate surface areas close to 100 μm².

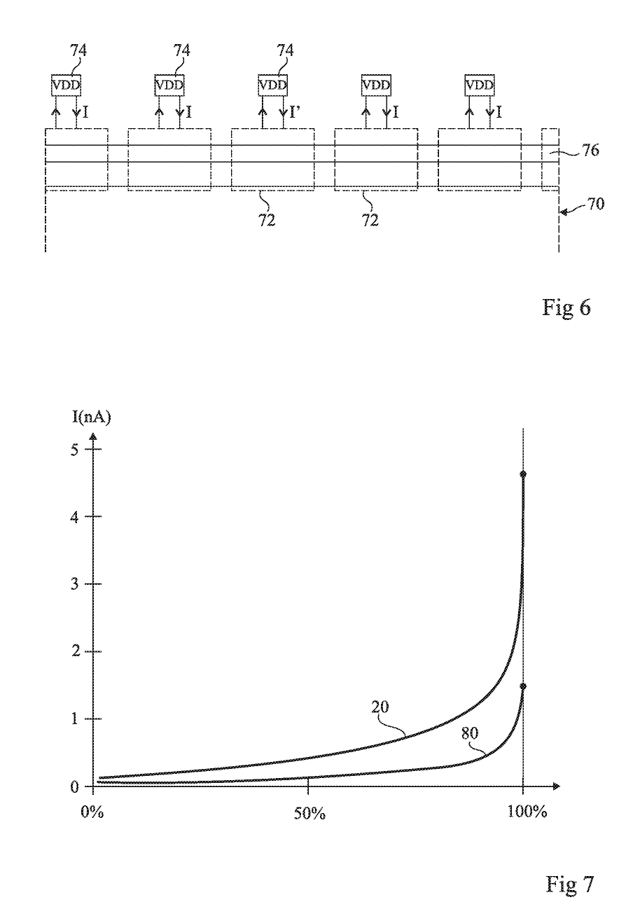

FIG. 6 is a partial simplified cross-section view of an embodiment of a FDSOI wafer 70 having a plurality of analog or digital circuits 72 designed to be identical formed inside and on top of it. Each circuit 72 is connected to a power supply circuit 74. The wafer will then be sawn into individual chips, each comprising one or a plurality of circuits 72 and the associated power supply circuit 74. Each circuit comprises many FDSOI-type field-effect transistors, for example, more than one thousand P-channel transistors and more than one thousand N-channel transistors. As an example, these transistors have gate surface areas smaller than 1 μm², for example, smaller than 0.1 μm².

As an example, the N-channel transistors have their channel regions P-type doped at an average level corresponding to the optimal value described hereabove in relation with FIG. 4, and the P-channel transistors have their channel regions N-type doped at an average level corresponding to a similar optimal value. For an N or P channel type, the average of the doping levels of the channel regions of the FDSOI transistors of this type of channel is here called average doping level of the channel regions. It should be noted that when the transistors have small gate surface areas, for example, smaller than 0.005 μm², the optimal value of the doping corresponds to a small average number of atoms in each transistor, for example, smaller than 2 atoms. Due to the randomness of the distribution of the dopant atoms, certain transistors may thus be doped to a level for example smaller than 10¹⁶ atoms/cm³, although the average doping level of the transistors corresponds to the optimal value. Thus, the provision of such an average doping level enables to limit differences between currents consumed by circuits comprising many transistors, although there may remain differences between the currents consumed by each transistor taken individually.

FIG. 7 schematically illustrates currents consumed by circuits of the type of circuit 72 of FIG. 6. The circuits have been classified in the increasing order of the consumed currents, and numbered between 0 and 100%. A curve 20 corresponds to circuits having FDSOI transistors with channel regions made of intrinsic semiconductor, and a curve 80 corresponds to circuits having FDSOI transistors with a specifically-doped channel region. Curves 20 and 80 have been obtained from experimental values. A decrease by a factor 5 of the current consumed by the circuits consuming the most power has been obtained.

Specific embodiments have been described. Various alterations, modifications, and improvements will occur to those skilled in the art. In particular, although neighboring N-channel transistors having a specifically P-type doped channel region have been described, it may be provided to N-type dope to a similar level the channel regions of neighboring P-channel FDSOI transistors.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

1. An electronic chip, comprising FDSOI-type field-effect transistors wherein each FDSOI-type field-effect transistor has a channel region doped at an average level in a range from 10¹⁶ to 5*10¹⁷ atoms/cm³ with a first dopant conductivity type opposite to a second dopant conductivity type for a drain region and a source region.

2. The chip of claim 1, wherein said range is between 10¹⁷ to 5*10¹⁷ atoms/cm³.

3. The chip of claim 1, wherein the channel regions of the FDSOI-type field-effect transistors have thicknesses in a range from 2.5 to 10 nm.

4. The chip of claim 1, wherein the channel regions of the FDSOI-type field-effect transistors have thicknesses in a range from 5.5 to 6.5 μm.

5. The chip of claim 1, wherein a gate surface area of the FDSOI-type field-effect transistors is greater than 1 μm².

6. The chip of claim 1, wherein said FDSOI-type field-effect transistors include two FDSOI-type field-effect transistors connected to form a current mirror.

7. The chip of claim 1, further comprising a power supply circuit coupled to the FDSOI-type field-effect transistors.

8. The chip of claim 1, wherein the FDSOI-type field-effect transistors each include a rear gate.

9. The chip of claim 8, wherein each rear gate is doped with the second dopant conductivity type.

10. An electronic chip, comprising FDSOI-type field-effect transistors wherein each FDSOI-type field-effect transistor has a channel region doped at an average level in a range between 10¹⁷ and 5*10¹⁷ atoms/cm³ with a first dopant conductivity type opposite to a second dopant conductivity type for a drain region and a source region.

11. The chip of claim 10, wherein the channel regions of the FDSOI-type field-effect transistors have thicknesses in a range from 2.5 to 10 nm.

12. The chip of claim 10, wherein the channel regions of the FDSOI-type field-effect transistors have thicknesses in a range from 5.5 to 6.5 μm.

13. The chip of claim 10, wherein a gate surface area of the FDSOI-type field-effect transistors is greater than 1 μm2.

14. The chip of claim 10, wherein said FDSOI-type field-effect transistors include two FDSOI-type field-effect transistors connected to form a current mirror.

15. The chip of claim 10, further comprising a power supply circuit coupled to the FDSOI-type field-effect transistors.

16. The chip of claim 10, wherein the FDSOI-type field-effect transistors each include a rear gate.

17. The chip of claim 16, wherein each rear gate is doped with the second dopant conductivity type.
